(19) United States
(12) Patent Application Publication
(10) Pub. No.: US 2024/0356304 A1
(43) Pub. Date: Oct. 24, 2024

(54) VCSEL, TRANSMITTER FOR TRANSMITTING OPTICAL SIGNAL PULSES COMPRISING A VCSEL, METHOD FOR OPERATING A VCSEL, AND METHOD FOR PRODUCING A VCSEL

(71) Applicant: TRUMPF Photonic Components GmbH, Ulm (DE)

(72) Inventor: Roman Koerner, Lonsee (DE)

(21) Appl. No.: 18/733,980

(22) Filed: Jun. 5, 2024

Related U.S. Application Data
(63) Continuation of application No. PCT/EP2022/084287, filed on Dec. 2, 2022.

(30) Foreign Application Priority Data
Dec. 6, 2021 (DE) 10 2021 132 083.6

(51) Int. Cl. H01S 5/30; H01S 5/026; H01S 5/042; H01S 5/183

(52) U.S. Cl. CPC H01S 5/3095; H01S 5/0262; H01S 5/0421; H01S 5/18327; H01S 5/1835

(57) ABSTRACT

A VCSEL includes a vertical resonator structure that includes a first Bragg reflector, a second Bragg reflector, and an active region, and a laser diode structure that includes a p-doped first region and an n-doped second region arranged on two sides of the active region, respectively. The vertical resonator structure further includes a tunnel diode structure having a highly n-doped first semiconductor layer and a highly p-doped second semiconductor layer. The VCSEL further includes an electrical contact arrangement having a first metal contact and a second metal contact defining a current path so that, for a voltage applied to the contact arrangement that is a reverse voltage in relation to the laser diode structure and a forward voltage in relation to the tunnel diode structure, charge carriers are conducted away from the vertical resonator structure via the tunnel diode structure into the second metal contact.

### CROSS REFERENCE TO RELATED APPLICATIONS

This application is a continuation of International Application No. PCT/EP2022/084287 (WO 2023/104668 A1), filed on Dec. 2, 2022, and claims benefit to German Patent Application No. DE 10 2021 132 083.6, filed on Dec. 6, 2021. The aforementioned applications are hereby incorporated by reference herein.

### FIELD

Embodiments of the present invention relate to a VCSEL comprising a vertical resonator structure constructed from semiconductor layers, to a transmitter for transmitting optical signal pulses, the transmitter having a VCSEL, to a method for operating a VCSEL, and to a method for producing a VCSEL.

### BACKGROUND

Vertical cavity surface emitting lasers (VCSELs) are used in many technical fields owing to their positive properties, such as a small design, low production costs, low energy consumption and their good beam quality. VCSELs are used inter alia in optical transmitters for data transmission and are suitable in particular for broadband signal transmission. However, the high-speed modulation of VCSELs obtainable nowadays is subject to natural limits caused by charge carrier transport phenomena. The modulation speed of a laser diode can be improved by an efficient charge carrier injection, a high differential gain and a greater photon density. The charge carrier density and the photon density in the laser cavity are not independent of one another, however, but rather are linked to one another by the relaxation resonant frequency, which describes the natural oscillation between charge carriers and photons in the laser cavity. It is therefore difficult to manipulate the charge carrier lifetime and the photon lifetime independently of one another.

In order to reduce the photon lifetime, use is often made of thin multi-quantum well structures embedded in a very short resonator with a high Q-factor. Such a VCSEL does offer a reduced photon lifetime, but has the disadvantage of a low extinction ratio owing to a reduced photon density in the laser. The differentiation between the on state and the off state of the laser is made more complicated for highly developed high-speed modulation methods. On the other hand, a high injection efficiency may lead to nonlinear effects of the amplification, and the modulation response decreases. The decay time of the laser (transition from the on state to the off state) then becomes the limiting factor.

### SUMMARY

Embodiments of the present invention provide a vertical cavity surface emitting laser (VCSEL). The VCSEL includes a vertical resonator structure constructed from semiconductor layers. The vertical resonator structure includes a first Bragg reflector, a second Bragg reflector, and an active region between the first Bragg reflector and the second Bragg reflector for generating light. The VCSEL further includes a laser diode structure. The laser diode structure includes a p-doped first region arranged on a first side of the active region, and an n-doped second region arranged on a second side of the active region opposite the first side. The vertical resonator structure further includes, between the first Bragg reflector and the second Bragg reflector, a tunnel diode structure having a highly n-doped first semiconductor layer and a highly p-doped second semiconductor layer. The highly n-doped first semiconductor layer is arranged nearer to the n-doped first region than the highly p-doped second semiconductor layer. The VCSEL further includes an electrical contact arrangement having a first metal contact and a second metal contact. The first metal contact and the second metal contact define a current path that leads through the tunnel diode structure and the laser diode structure in such a way that, for a voltage applied to the contact arrangement that is a reverse voltage in relation to the laser diode structure and a forward voltage in relation to the tunnel diode structure, charge carriers are conducted away from the vertical resonator structure via the tunnel diode structure into the second metal contact.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 schematically shows a layer construction of a VCSEL according to some embodiments;

FIG. 2 shows a VCSEL with electrical contact arrangement according to some embodiments;

FIG. 3 shows a modified VCSEL with electrical contact arrangement by comparison with FIG. 2, according to some embodiments;

FIG. 4a) shows the VCSEL in FIG. 2 in the on state, the associated current path being illustrated, according to some embodiments,

FIG. 4b) shows a voltage-time diagram for illustrating a method for operating the VCSEL, according to some embodiments;

FIG. 5a) shows the VCSEL in FIG. 2 in the off state, the associated current path being illustrated, according to some embodiments;

FIG. 5b) shows a voltage-time diagram in FIG. 4b) for further illustrating the method for operating the VCSEL, according to some embodiments;

FIG. 6 shows a block diagram of a transmitter for transmitting optical signal pulses comprising a VCSEL according to some embodiments; and

FIG. 7 shows a flow diagram of a method for producing a VCSEL according to some embodiments.

### DETAILED DESCRIPTION

Embodiments of the invention provide an improved VCSEL which is suitable for high-speed modulation methods.

Embodiments of the invention also provide a transmitter for transmitting optical signal pulses comprising such a VCSEL.

Embodiments of the invention also provide a method for operating a VCSEL.

Embodiments of the invention further provide a method for producing a VCSEL.

According to some embodiments, a VCSEL includes a vertical resonator structure constructed from semiconductor layers and having a first Bragg reflector, a second Bragg reflector and, between the first Bragg reflector and the second Bragg reflector, an active region for generating light, wherein a p-doped first region is arranged on a first side of the active region and an n-doped second region is arranged on a second side of the active region opposite the first side in order to form a laser diode structure, wherein the resonator structure, between the first and second Bragg reflectors, furthermore has a tunnel diode structure having a highly n-doped first semiconductor layer and a highly p-doped second semiconductor layer, wherein the highly n-doped first semiconductor layer is arranged nearer to the n-doped first region than the highly p-doped second semiconductor layer, and comprising an electrical contact arrangement having a first metal contact and a second metal contact, wherein the first and second metal contacts define a current path that leads through the tunnel diode structure and the laser diode structure in such a way that in the case of a voltage which is applied to the contact arrangement and which is a reverse voltage in relation to the laser diode structure and a forward voltage in relation to the tunnel diode structure, charge carriers are conducted away from the resonator structure via the tunnel diode structure into the second metal contact.

In the case of the VCSEL according to embodiments of the invention, a tunnel diode is integrated into the resonator structure for the purpose of very rapidly carrying away charge carriers at least from parts of the resonator structure, in particular from the active region and the layers surrounding the active region of the laser diode structure. The charge carrier depletion takes place instantaneously when a voltage which is a reverse voltage for the laser diode structure but a forward voltage for the tunnel diode structure is applied to the tunnel diode structure. In this case, a current path is opened up via the tunnel diode structure and the charge carriers can flow away to the second metal contact via said current path. If a voltage which is a forward voltage for the laser diode structure is applied to the VCSEL, the depletion current path via the tunnel diode is eliminated, and so no charge carriers can flow away, rather the entire current flows through the active region of the laser diode structure.

In the case of the VCSEL according to embodiments of the invention, the decay time from the on state to the off state of the VCSEL is significantly reduced, and so very good differentiation between the on state and the off state of the VCSEL becomes possible. The light emission of the VCSEL can thus be modulated between the on and off states at very high speed.

The entire VCSEL can be drained of charge carriers by a slight forward voltage in relation to the tunnel diode structure being applied (approximately −0.5 V; the minus sign signifies that the voltage is a reverse voltage in relation to the laser diode structure), said voltage enabling Esaki band-to-band tunneling in the tunnel diode structure. Since the tunneling time duration is in the femtoseconds range, the switch-off of the laser under the effect of “tunnel depletion” takes place more rapidly than is possible by way of the natural decay time of the VCSEL. Even for higher charge carrier densities within the active region and therefore high extinction ratios between the levels in the on state and the off state, this depletion mechanism amplified by the tunnel effect enables very rapid decay of the laser emission. A further advantage is that parasitic capacitances can be eliminated or at least reduced by the depletion of free charge carriers within the VCSEL, as a result of which an accumulation of charge is reduced.

If a higher forward voltage in relation to the laser diode structure is applied to the contact arrangement, an additional current path through the tunnel diode structure, which is reverse-biased in this case, can be established, which can advantageously lead to a reduction of inhomogeneities in the current density on the n-contact side.

It is advantageous if the second metal contact directly contacts the highly n-doped first semiconductor layer and the highly p-doped second semiconductor layer of the tunnel structure.

In this configuration, the second metal contact short-circuits the tunnel diode structure. The second metal contact is an n/p-hybrid contact in this case. The current injection for generating light takes place via the n-conducting semiconductor layer of the tunnel diode structure in this case. The tunnel contact thus created within the laser cavity brings about a reduced current path length to the metal contact. This leads to overall a reduced ohmic resistance. As a result, as is provided in a further preferred configuration, the second Bragg reflector can be a non-doped region of the resonator structure, which in turn has the advantage of reducing the absorption of the generated laser light by the second Bragg reflector. Moreover, this simplifies the production of the VCSEL.

Furthermore, it is advantageous if the tunnel diode structure is adjacent to an n-doped contact layer adjoining the highly n-doped semiconductor layer, and/or is adjacent to a p-doped contact layer adjoining the highly p-doped semiconductor layer. The second metal contact here contacts the n-doped and p-doped contact layers and also the tunnel diode structure layers. Owing to the inverse polarization of the tunnel diode structure, the current in the case of a forward voltage applied in relation to the laser diode structure is blocked in the p-doped region of the tunnel diode structure, which enables a current path through the n-doped region of the tunnel diode structure to the second mental contact. This simplifies the production of the second metal contact as an intracavity contact since the second metal contact embodied in the shape of a crown in this way can be applied over the entire tunnel diode structure.

The resonator structure can be constructed from the material system AlGaAs/GaAs, wherein the abovementioned n-doped contact layer and/or the p-doped contact layer can be GaAs layers.

In an alternative configuration, a p-doped contact layer can be adjacent to the highly p-doped semiconductor layer of the tunnel diode structure, wherein the second metal contact only contacts the p-doped contact layer. In this configuration, the second metal contact does not short-circuit the p- and n-conducting layers of the tunnel diode structure. The second metal contact is a p-contact in this configuration.

The first metal contact advantageously contacts a p-conducting contact layer arranged on the first Bragg reflector.

The first Bragg reflector is accordingly preferably a p-doped region of the resonator structure.

Overall, the VCSEL according to embodiments of the invention can have a p-i-n-n⁺-p⁺-p-i structure, wherein the first intrinsic region is the active region and the second region is the second Bragg reflector, and wherein the n⁺- and p⁺-layers form the tunnel diode structure.

In a further embodiment, the p-doped first region on the first side of the active region and the n-doped second region on the second side of the active region can have an SCH (separate confinement heterostructure) structure. The p-doped first region can also comprise the first Bragg reflector.

The resonator structure can have a mesa, wherein the semiconductor layers of the tunnel diode structure and of the laser diode structure are arranged in the mesa.

In this configuration, the second metal contact is preferably a p-contact that contacts a p-conducting contact layer.

Alternatively, the resonator structure can have a mesa, wherein the semiconductor layers of the tunnel and a structure are arranged outside the mesa.

In this configuration, the second metal contact is preferably an n/p-hybrid contact, as described above.

Embodiments of the invention also provide a transmitter for transmitting optical signal pulses, comprising a VCSEL according to embodiments of the invention, and comprising an electrical driver, wherein the driver is designed, in order for an optical signal pulse to be emitted by the VCSEL, to apply a first voltage to the contact arrangement, which first voltage is a forward voltage in relation to the laser diode structure and a reverse voltage in relation to the tunnel diode structure, and, in order for the emission to be switched off, to apply a second voltage to the contact arrangement, which second voltage is a forward voltage in relation to the tunnel diode structure and a reverse voltage in relation to the laser diode structure.

Embodiments of the invention also provide a method for operating a VCSEL according to the invention, comprising the following steps:
applying a first voltage to the contact arrangement, which first voltage is a forward voltage in relation to the laser diode structure, in order that a light pulse is emitted by the VCSEL,
applying a second voltage to the contact arrangement, which second voltage has an opposite sign to the first voltage and is a forward voltage in relation to the tunnel diode structure, in order that the emission by the VCSEL is switched off.

In this case, the first voltage can be greater than the second voltage in terms of absolute value. As already described above, a low forward voltage U (U<0 V) at the tunnel diode structure is sufficient for depleting the charge carriers from the semiconductor layers surrounding the active region.

The absolute value of the first voltage can be chosen with a magnitude so as to give rise to an additional current path through the tunnel diode structure operated in the reverse direction at the first voltage. In this case, the additional current path arises as a result of the Zener current through the tunnel diode structure.

Embodiments of the invention also provide a method for producing a VCSEL, comprising the following steps:
fabricating a vertical resonator structure made from semiconductor layers and having a first Bragg reflector, a second Bragg reflector and, between the first Bragg reflector and the second Bragg reflector, an active region for generating light, wherein a p-doped first region is arranged on a first side of the active region and an n-doped second region is arranged on a second side of the active region opposite the first side in order to form a laser diode structure, wherein the resonator structure, between the first and second Bragg reflectors, furthermore has a tunnel diode structure having a highly n-doped first semiconductor layer and a highly p-doped second semiconductor layer, wherein the highly n-doped first semiconductor layer is arranged nearer to the n-doped first region than the highly p-doped second semiconductor layer,
contacting the VCSEL with an electrical contact arrangement having a first metal contact and a second metal contact, wherein the first and second metal contacts define a current path that leads through the tunnel diode structure and the laser diode structure in such a way that in the case of a voltage which is applied to the contact arrangement and which is a reverse voltage in relation to the laser diode structure and a forward voltage in relation to the tunnel diode structure, charge carriers are conducted away from the resonator structure via the tunnel diode structure into the second metal contact.

It goes without saying that the transmitter for transmitting optical signal pulses, the method for operating a VCSEL, and the method for producing a VCSEL have advantages the same as or similar to those of the VCSEL according to one or more of the configurations mentioned above.

It likewise goes without saying that the transmitter, the method for operating and the method for producing a VCSEL can have the same preferred configurations as the VCSEL.

Further advantages and features are evident from the following description and the accompanying drawing. It goes without saying that the abovementioned features and the features to be explained below are usable not only in the respectively specified combination but also in other combinations or on their own, without departing from the scope of the present invention.

Embodiments of the present invention relate to a surface emitting laser comprising a vertical resonator structure, a VCSEL for short, in which a tunnel diode structure is integrated into the resonator structure and serves to shorten the decay time during the transition from the on state to the off state of the VCSEL. A VCSEL in accordance with the present disclosure is thus suitable in particular for applications in which the VCSEL is operated at a high modulation speed.

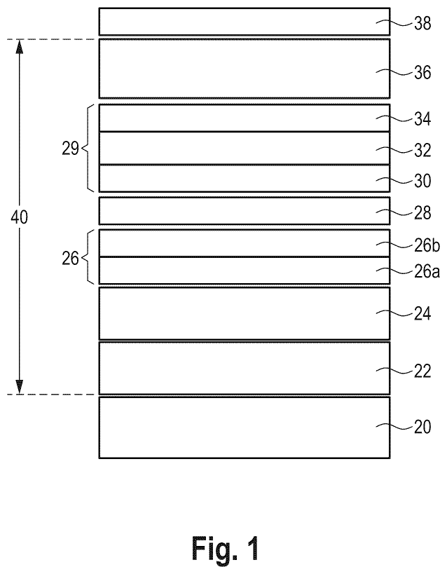

Referring to FIG. 1, firstly a layer construction of such a VCSEL will be described.

The semiconductor layer construction has a substrate 20, which can be n-doped. The substrate can alternatively also be undoped. The substrate 20 serves as a wafer for epitaxially growing the semiconductor layers to be described below.

A Bragg reflector 22 is arranged on the substrate 20. The Bragg reflector 22, also referred to as DBR (distributed Bragg reflector), typically has a plurality of semiconductor layer pairs, wherein each pair has a high refractive index layer and a low refractive index layer. The Bragg reflector 22 is preferably a non-doped region, i.e. the semiconductor layer of the Bragg reflector 22 is constructed from an intrinsic semiconductor system. In the present description, “intrinsic” means that the semiconductor layers are not deliberately doped with impurity atoms, although “intrinsic” does not exclude the presence of a small amount of impurity atoms.

Adjacent to the Bragg reflector 22 there is a contact layer 24. The contact layer 24 is in particular a p-conducting contact layer. The contact layer 24 can have a thickness in the range of 50 nm to 150 nm.

A tunnel diode structure 26 is arranged on the contact layer 24. The tunnel diode structure 26 has at least one highly p-doped layer 26a and at least one highly n-doped layer 26b. The layer thickness of the at least one highly p-doped layer 26a and the layer thickness of the at least one highly n-doped layer 26b can each be in the range of 5 nm to 25 nm.

Adjacent to the tunnel diode structure 26 there is a further contact layer 28, which is an n-conducting contact layer. The n-contact layer 28 can have a layer thickness in the range of 25 nm to 75 nm.

Adjacent to the n-contact layer 28 there is a laser diode structure 29 having an active region 32 and respective SCH structures 30 and 34 on both sides of the active region 32 (SCH: Separate Confinement Heterostructure). The SCH structure 30 is an n-doped region of the semiconductor layer structure, and the SCH structure 34 is a p-doped region of the semiconductor layer structure.

Adjacent to the laser diode structure 29 there is a further Bragg reflector 36, which is a p-doped region of the semiconductor layer construction in the present case.

Arranged on the Bragg reflector 36 there is a further contact layer 38, which is a p-conducting contact layer.

The semiconductor layers from the Bragg reflector 22 as far as the Bragg reflector 36 form a vertical resonator structure 40.

The highly n-doped layer or layers 26b of the tunnel diode structure 26 is/are arranged nearer to the n-doped region 30 of the laser diode structure than the highly p-doped layer or layers 26a of the tunnel diode structure 26. This means that the polarity of the p-n junction in the tunnel diode structure 26 is opposite to the polarity of the p-n junction in the laser diode structure 29. The doping of the n⁺- and p⁺-layers can be higher than 10¹⁹ cm³.

The active region 32 can have one or more quantum wells.

The semiconductor layers of the layer construction of the VCSEL can be based in particular on the material system aluminum gallium arsenide/gallium arsenide (AlGaAs/GaAs). The substrate 20 can consist of GaAs. The two Bragg reflectors 22 and 36 can consist of AlGaAs/GaAs layers. The p-contact layer 24 can be formed from GaAs. The layers 26a, 26b of the tunnel diode structure 26 can be formed from GaAs. The n-contact layer 28 can be formed from GaAs. The layers of the SCH structures 30, 34 can be formed from AlGaAs. The active region 32 can have one or more quantum wells composed of AlGaAs/GaAs layers. The p-contact layer 38 can be formed from GaAs.

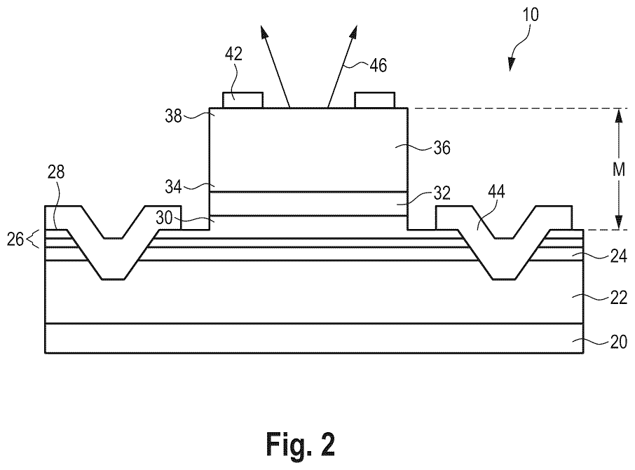

FIG. 2 shows a VCSEL having the layer construction in accordance with FIG. 1, the VCSEL being provided with the general reference sign 10. In order to simplify the illustration, some of the semiconductor layers or regions of the layer construction in FIG. 1 have been combined in a block-like manner in FIG. 2.

In accordance with FIG. 2, the layer construction in FIG. 1 was etched after epitaxial growth in order to form a mesa M in the resonator structure 40. In this case, the mesa M comprises the p-contact layer 38, the Bragg reflector 36, and the laser diode structure 29 comprising the SCH structures 30 and 34. By contrast, the tunnel diode structure 26 together with the n-contact layer 28 and the p-contact layer 24 is embodied over the full area on the substrate 20, where “over the full area” should also be understood to mean that the layers 24, 26, 28 extend on the substrate 20 laterally further than the mesa M, but without extending over the entire area of the substrate 20.

The VCSEL furthermore has an electrical contact arrangement having a metal contact 42 and a metal contact 44. The metal contact 42 is arranged on the p-contact layer 38 and accordingly embodied as a p-contact. The metal contact 42 can be embodied in particular in ring-shaped fashion, such that laser light generated in the active region 32 can be emitted through the ring-shaped metal contact 42, as is indicated by arrows 46. The metal contact 42 can extend fully circumferentially, or else only in sections.

The metal contact 44 of the electrical contact arrangement, as shown in FIG. 2, can likewise be embodied in ring-shaped fashion. The metal contact 44 can be embodied fully circumferentially or only in sections. The metal contact 44 contacts the n-contact layer 28 and the p-contact layer 24 and the intervening highly doped n- and p-layers of the tunnel diode structure 26. The metal contact 44 is thus an n/p-hybrid contact.

The metal contact 44 is embodied in crown-like fashion and extends through the layers 24, 26a, 26b and 28. The metal contact 44 directly contacts the highly doped n- and p-layers of the tunnel diode structure. In this exemplary embodiment, the metal contact 44 together with the tunnel diode structure 26 forms an intra-resonator tunnel diode contact.

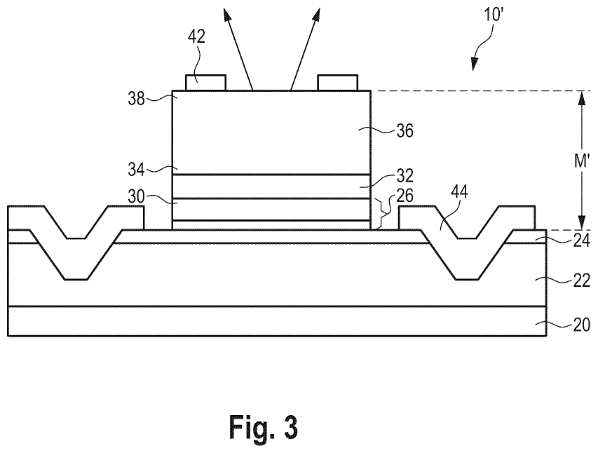

FIG. 3 shows a modified exemplary embodiment of a VCSEL 10′ by comparison with FIG. 2. The VCSEL 10′ likewise has the semiconductor layer structure from FIG. 1. The VCSEL 10′ differs from the VCSEL 10 in FIG. 2, however, in that the mesa M′ was etched down to the p-contact layer 24. The semiconductor layers of the tunnel diode structure 26 are therefore arranged together with the laser diode structure 29 within the mesa M′. In this exemplary embodiment, the metal contact 44 contacts only the p-contact layer 24. In this case, the metal contact 44 is embodied as a p-contact, and so is the metal contact 42.

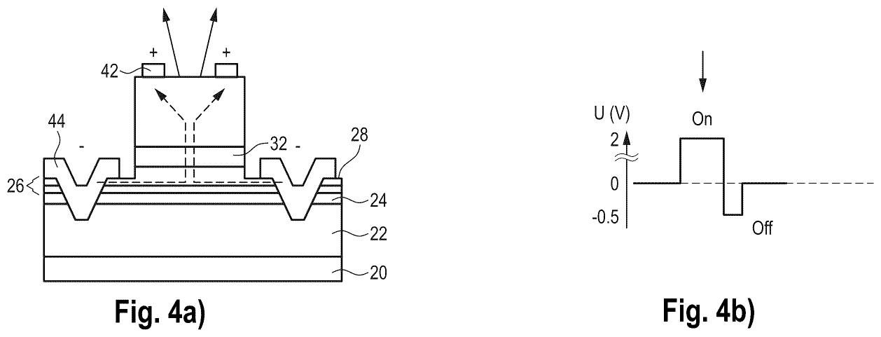

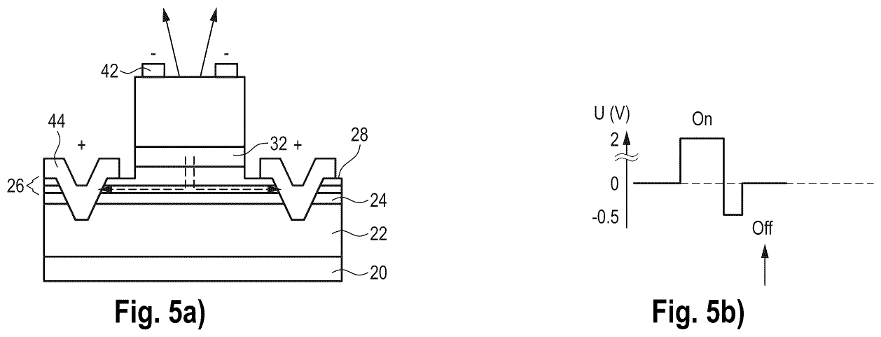

Referring to FIGS. 4a), 4b) and 5a), 5b), on the basis of the exemplary embodiment of the VCSEL 10 in FIG. 2, a method for operating the VCSEL 10 is described, the description also illustrating the functioning of the tunnel diode structure 26.

FIG. 4a) shows the case where a voltage U which is a forward voltage in relation to the laser diode structure 29 is applied to the metal contacts 42 and 44, as is indicated by +above the metal contact 42 and —above the metal contact 44. In the case of such a positive voltage which is a forward voltage for the laser diode structure 29, the tunneldiode structure 26 is reverse-biased. Owing to the inverse polarization of the tunnel diode structure 26 relative to the laser diode structure 26, the current is blocked in the p-doped region of the tunnel diode structure 26, while a current path arises through the n-doped region of the tunnel diode structure 26 and through the laser diode structure 29 to the metal contact 42, whereby the active region 32 of the laser diode structure 29 is excited to effect stimulated emission. FIG. 4a) indicates the current path using interrupted lines between the metal contact 44 and the metal contact 42.

The voltage U can be 2 V, for example, as is shown in FIG. 4b). The VCSEL is switched on by the positive voltage U being applied, as is illustrated by “on”. The metal contact 44 is an n-contact in this case. If the positive voltage assumes a higher value, and additional conductivity can arise through the tunnel diode structure 26 as Zener current.

In order to change over the VCSEL from the on state to the off state, in accordance with FIG. 5a), a slightly negative voltage U of approximately −0.5 V is applied to the metal contacts 42 and 44, which voltage is a reverse voltage in relation to the laser diode structure 29 and a forward voltage in relation to the tunnel diode structure 26. This is illustrated by—above the metal contact 42 and +above the metal contact 44. Since the laser diode structure 29 is now reverse-biased, while the tunnel diode structure 26 is forward-biased with a slight voltage, the tunnel diode structure 26 causes charge carriers to be conducted away via the tunnel diode structure 26 from the active region 32 and the semiconductor layers adjoining the active region 32 or surrounding the latter, as is indicated by the interrupted current arrows. The slightly negative voltage, for example −0.5 V, enables Esaki band-to-band tunneling in the tunnel diode structure 26. Since the tunneling time is in the femtoseconds range, this “tunnel depletion switch-off” takes place more rapidly than the natural switch-off of the VCSEL, i.e. the decay time of the light emission is significantly shorter than without the tunnel diode structure. The off state of the VCSEL 10 is thus reached more rapidly than without the tunnel diode structure 26. In FIG. 5b), the off state is identified by “off”.

Even at higher charge carrier densities within the quantum wells of the active region 32 and therefore high extinction ratios between the level in the on state and the level in the off state, this depletion mechanism amplified by the tunnel effect enables a very short decay time of the VCSEL. The VCSEL 10 can therefore be changed over from the on state to the off state more rapidly than a conventional VCSEL.

In the exemplary embodiment in FIG. 2, the intra-resonator contact 44 offers a reduced current path length on the n-conducting side to the metal contact 44. As a result, the ohmic resistance is reduced overall. What is furthermore made possible as a result is that the Bragg reflector 22 below the tunnel diode structure 26 need not be doped, since it does not have to contribute to the conductivity, whereby the optical absorption in the Bragg reflector 22 is advantageously reduced.

In the exemplary embodiment in FIG. 3, the metal contact 44 is a p-contact and is in contact only with the p-contact layer 24. In this exemplary embodiment, too, the polarity of the tunnel diode structure 26 is opposite to the polarity of the laser diode structure 29. In the case of a positive voltage applied to the metal contacts 42 and 44 (cf. FIG. 4a)), the current flow for pumping the active region 32 takes place through the tunnel diode structure 26, the Zener current flowing through the tunnel diode structure in this case. By virtue of applying a slightly negative voltage which is accordingly a reverse voltage for the laser diode structure 29, while it is a forward voltage for the tunnel diode structure 26, in order to reduce the decay time of the laser emission, once again charge carriers are conducted away from the active region 32 and the semiconductor layers surrounding the active region, or the semiconductor layers adjoining the active region, via the tunnel diode structure 26.

The VCSEL 10 and the VCSEL 10′ are suitable in particular for transmitters for transmitting optical signal pulses with high modulation speed.

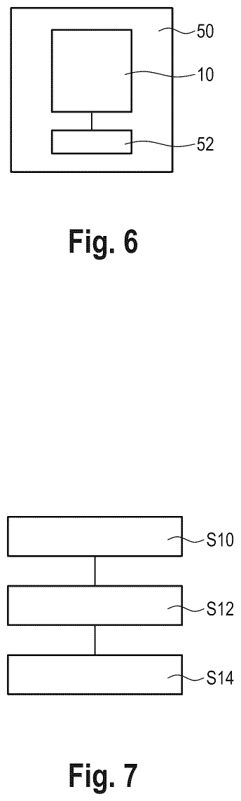

FIG. 6 shows a transmitter 50, comprising the VCSEL 10 (or the VCSEL 10′) and an electrical driver 52. The driver 52 is designed, in order for an optical signal pulse to be emitted, to apply a first voltage to the contact arrangement 42, 44, which first voltage is a forward voltage in relation to the laser diode structure 29 and a reverse voltage in relation to the tunnel diode structure 26, and, in order for the emission to be switched off, to apply a second voltage to the contact arrangement 44, 46, which second voltage is a forward voltage in relation to the tunnel diode structure 26 and a reverse voltage in relation to the laser diode structure 29, as described above.

The first voltage can be greater than the second voltage in terms of absolute value. The absolute value of the first voltage can be chosen with a magnitude so as to give rise to an additional current path through the tunnel diode structure 26 operated in the reverse direction at the first voltage.

FIG. 7 shows a flow diagram of a method for producing the VCSEL 10 or the VCSEL 10′.

In a step S10, the vertical resonator structure 40 is fabricated. In this case, the vertical resonator structure 40 is grown epitaxially on the substrate 20. The epitaxial growth of the semiconductor layers is preferably carried out continuously without interruption. The thicknesses and also the doping concentrations of the different semiconductor layers are defined by the epitaxy.

On the epitaxially grown resonator structure 40, the p-contact layer 38 is also grown in the same method sequence.

In a step 512, the layer construction is etched in order to form the mesa M or the mesa M′.

The etching of the mesa M or M′ can be followed by a step for producing a current aperture stop. The current aperture stop can be realized by oxidation of one or more of the semiconductor layers, in particular of an aluminum-containing layer (for example AlGaAs). A current aperture can alternatively be produced by ion implantation.

In a step S14, the VCSEL is contacted with the electrical contact arrangement 42, 44. In this case, the metal contacts 42, 44 define a current path that leads through the tunnel diode structure 26 and the laser diode structure 29, such that in the case of a voltage which is applied to the contact arrangement and which is a reverse voltage in relation to the laser diode structure 29 and a forward voltage in relation to the tunnel diode structure 26, charge carriers are conducted away via the tunnel diode structure 26.

In the exemplary embodiments shown, the VCSEL 10 or the VCSEL 10′ is embodied as a top emitter, i.e. light is emitted through the side of the VCSEL 10 or 10′ facing away from the substrate 22. The Bragg reflector 22 correspondingly has a higher reflectivity than the Bragg reflector 36. In this case, the reflectivity of the Bragg reflector 22 can be more than 99.5%, while the reflectivity of the Bragg reflector 36 can be less than 99%, for example approximately 98%.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “of” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A vertical cavity surface emitting laser (VCSEL), comprising:
a vertical resonator structure constructed from semiconductor layers, the vertical resonator structure comprising:
a first Bragg reflector,
a second Bragg reflector, and
an active region between the first Bragg reflector and the second Bragg reflector for generating light,
a laser diode structure comprising:
a p-doped first region arranged on a first side of the active region, and
an n-doped second region arranged on a second side of the active region opposite the first side,
wherein the vertical resonator structure further comprises, between the first Bragg reflector and the second Bragg reflector, a tunnel diode structure having a highly n-doped first semiconductor layer and a highly p-doped second semiconductor layer, wherein the highly n-doped first semiconductor layer is arranged nearer to the n-doped first region than the highly p-doped second semiconductor layer, and
the VCSEL further comprising an electrical contact arrangement having a first metal contact and a second metal contact, wherein the first metal contact and the second metal contact define a current path that leads through the tunnel diode structure and the laser diode structure in such a way that, for a voltage applied to the contact arrangement that is a reverse voltage in relation to the laser diode structure and a forward voltage in relation to the tunnel diode structure, charge carriers are conducted away from the vertical resonator structure via the tunnel diode structure into the second metal contact.

2. The VCSEL as claimed in claim 1, wherein the second metal contact directly contacts the highly n-doped first semiconductor layer and the highly p-doped second semiconductor layer of the tunnel diode structure.

3. The VCSEL as claimed in claim 1, further comprising an n-doped contact layer adjoining the highly n-doped semiconductor layer, and/or a p-doped contact layer adjoining the highly p-doped semiconductor layer.

4. The VCSEL as claimed in claim 3, wherein the vertical resonator structure is constructed from AlGaAs/GaAs materials, and wherein the n-doped contact layer and the p-doped contact layer comprises GaAs.

5. The VCSEL as claimed in claim 3, wherein the second metal contact contacts the n-doped contact layer and the p-doped contact layer.

6. The VCSEL as claimed in claim 1, further comprising a p-doped contact layer adjoining the highly p-doped second semiconductor layer, wherein the second metal contact only contacts the p-doped contact layer.

7. The VCSEL as claimed in claim 1, wherein the second Bragg reflector is a non-doped region of the vertical resonator structure.

8. The VCSEL as claimed in claim 1, further comprising a p-doped contact layer arranged on the first Bragg reflector, wherein the first metal contact contacts the p-doped contact layer.

9. The VCSEL as claimed in any of claim 1, wherein the first Bragg reflector is a p-doped region of the vertical resonator structure.

10. The VCSEL as claimed in claim 1, wherein the p-doped first region on the first side of the active region and the n-doped second region on the second side of the active region have a separate confinement heterostructure (SCH) structure.

11. The VCSEL as claimed in claim 1, wherein the vertical resonator structure has a mesa, wherein the tunnel diode structure and the laser diode structure are arranged in the mesa.

12. The VCSEL as claimed in claim 1, wherein the vertical resonator structure has a mesa, wherein the tunnel diode structure is arranged outside the mesa.

13. A transmitter for transmitting optical signal pulses, the transmitter comprising a VCSEL as claimed in claim 1, and an electrical driver, wherein the electrical driver is configured to apply a first voltage to the contact arrangement so as to cause the VCSEL to emit an optical signal pulse, wherein the first voltage is a forward voltage in relation to the laser diode structure and a reverse voltage in relation to the tunnel diode structure, and wherein the electrical driver is configured to apply a second voltage to the contact arrangement so as to switch off the emission, wherein the second voltage is a forward voltage in relation to the tunnel diode structure and a reverse voltage in relation to the laser diode structure.

14. A method for operating a VCSEL as claimed in claim 1, the method comprising:
applying a first voltage to the contact arrangement, wherein the first voltage is a forward voltage in relation to the laser diode structure, so that a light pulse is emitted by the VCSEL,
applying a second voltage to the contact arrangement, wherein the second voltage has an opposite sign to the first voltage and is a forward voltage in relation to the tunnel diode structure, so that the emission by the VCSEL is switched off.

15. The method as claimed in claim 14, wherein an absolute value of the first voltage is greater than an absolute value of the second voltage.

16. The method as claimed in claim 14, wherein an absolute value of the first voltage is chosen with a magnitude so as to give rise to an additional current path through the tunnel diode structure operated in a reverse direction at the first voltage.

17. A method for producing a VCSEL, the method comprising:
fabricating a vertical resonator structure made from semiconductor layers, the vertical resonator structure comprising:
a first Bragg reflector,
a second Bragg reflector, and
an active region between the first Bragg reflector and the second Bragg reflector for generating light,
forming a p-doped first region on a first side of the active region and an n-doped second region on a second side of the active region opposite the first side in order to form a laser diode structure, wherein the resonator structure, between the first and second Bragg reflectors,
forming a tunnel diode structure, the tunnel diode structure comprising a highly n-doped first semiconductor layer and a highly p-doped second semiconductor layer, wherein the highly n-doped first semiconductor layer is arranged nearer to the n-doped first region than the highly p-doped second semiconductor layer,
contacting the VCSEL with an electrical contact arrangement, the electrical contact arrangement having a first metal contact and a second metal contact, wherein the first metal contact and the second metal contact define a current path that leads through the tunnel diode structure and the laser diode structure in such a way that, for a voltage applied to the contact arrangement that is a reverse voltage in relation to the laser diode structure and a forward voltage in relation to the tunnel diode structure, charge carriers are conducted away from the vertical resonator structure via the tunnel diode structure into the second metal contact.
